(19) United States
(12) Patent Application Publication
(10) Pub. No.: US 2015/0129586 A1
(43) Pub. Date: May 14, 2015

(54) MICROWAVE HEATING APPARATUS AND PROCESSING METHOD

(71) Applicant: Tokyo Electron Limited, Tokyo (JP)

(72) Inventors: Taro IKEDA, Nirasaki (JP); Jun YAMASHITA, Nirasaki (JP); Seokhyoung HONG, Nirasaki (JP); Kouji SHIMOMURA, Nirasaki (JP); Hiroyuki HAYASHI, Nirasaki (JP)

(21) Appl. No.: 14/603,910

(22) Filed: Jan. 23, 2015

Related U.S. Application Data
(63) Continuation of application No. PCT/JP2013/066017, filed on Jun. 11, 2013.

(30) Foreign Application Priority Data
Jul. 25, 2012 (JP) 2012-164542

(51) Int. Cl. H05B 6/80; H01L 21/324

(52) U.S. Cl. CPC H05B 6/806; H01L 21/324
USPC 219/754; 219/762

(57) ABSTRACT

A microwave heating apparatus includes a processing chamber having a top wall, a bottom wall and a sidewall, and configured to accommodate an object to be processed; a microwave introducing unit configured to generate a microwave for heating the object and introduce the microwave into the processing chamber; a plurality of supporting members configured to make contact with the object and support the object in the processing chamber. The microwave heating apparatus further includes a dielectric member provided between the object supported by the supporting members and the bottom wall while being apart from the object.

### CROSS-REFERENCE TO RELATED APPLICATIONS

This application is a Continuation Application of PCT International Application No. PCT/JP2013/066017 filed on 11 Jun. 2013, which designated the United States, and claims priority to Japanese Patent Application No. 2012-164542 filed on Jul. 25, 2012, the entire contents of which are incorporated herein by reference.

### FIELD OF THE INVENTION

The present invention relates to a microwave heating apparatus for performing predetermined processing by introducing a microwave into a processing chamber and a processing method for heating an object to be processed by using the microwave heating apparatus.

### BACKGROUND OF THE INVENTION

As an LSI device or a memory device is miniaturized, a depth of a diffusion layer in a transistor manufacturing process is decreased. Conventionally, doping atoms implanted to the diffusion layer are activated by a high-speed heating process referred to as an RTA (Rapid Thermal Annealing) using a lamp heater. However, in the RTA process, since the diffusion of the doping atoms progresses, the depth of the diffusion layer exceeds a tolerable range, which makes difficult a miniaturized design. If the depth of the diffusion layer is incompletely controlled, the electrical characteristics of devices deteriorate due to occurrence of leakage current or the like.

Recently, an apparatus using a microwave is suggested as an apparatus for performing heat treatment on a semiconductor wafer. When doping atoms are activated by microwave heating, a microwave directly acts on the doping atoms and, this, excessive heating does not occur and extension of a diffusion layer can be suppressed.

An organic substance peeling apparatus including a rotatable supporting table for supporting a semiconductor wafer and an electromagnetic wave irradiation unit for heating the semiconductor wafer is suggested in, e.g., Japanese Patent Application Publication No. 2001-156049, as the heating apparatus using a microwave.

The microwave has a long wavelength of several tens of millimeters and has a feature that standing waves can be easily formed in the processing chamber. Accordingly, when the semiconductor wafer is heated by using the microwave, for example, an intensity distribution of an electromagnetic field becomes non-uniform in the surface of the semiconductor wafer, which is likely to result in non-uniform heating temperature. Further, the semiconductor wafer has low microwave absorption efficiency so that heating of the semiconductor wafer may be insufficient, which is problematic in terms of effective use of power.

In view of the above, the present invention provides a microwave heating apparatus and a heating method capable of uniformly and effectively heating an object to be processed.

In accordance with the present invention, there is provided a microwave heating apparatus including: a processing chamber having a top wall, a bottom wall and a sidewall, and configured to accommodate an object to be processed; a microwave introducing unit configured to generate a microwave for heating the object and introduce the microwave into the processing chamber; a plurality of supporting members configured to make contact with the object and support the object in the processing chamber; and a dielectric member provided between the object supported by the supporting members and the bottom wall while being apart from the object.

In the microwave heating apparatus and the processing method of the present invention, the object to be processed can be uniformly and effectively heated.

### BRIEF DESCRIPTION OF THE DRAWINGS

FIG. 1 is a cross sectional view showing a schematic configuration of a microwave heating apparatus in accordance with a first embodiment of the present invention;

FIG. 2 is a perspective view showing a dielectric plate to which supporting pins are installed in the first embodiment of the present invention;

FIG. 3A is a view for explaining vertical positions of the dielectric plate, the supporting pins and a semiconductor wafer in the first embodiment of the present invention;

FIG. 3B is an enlarged cross sectional view showing a configuration around the dielectric plate in the first embodiment of the present invention;

FIG. 4 is a view for explaining a schematic configuration of a high voltage power supply unit of a microwave introducing unit in the first embodiment of the present invention;

FIG. 5 is a top view showing a top surface of a ceiling portion of a processing chamber shown in FIG. 1;

FIG. 6 is a view for explaining a structure of a control unit shown in FIG. 1;

FIG. 7 is a cross sectional view showing a schematic configuration of a microwave heating apparatus in accordance with a second embodiment of the present invention;

FIG. 8 is a perspective view showing supporting pins and a dielectric plate in the second embodiment of the present invention; and

FIGS. 9A to 9C are graphs showing results of simulation of efficiency of absorption of microwave power by a wafer.

### DETAILED DESCRIPTION OF THE EMBODIMENTS

Hereinafter, embodiments of the present invention will be described with reference to the accompanying drawings.

### First Embodiment

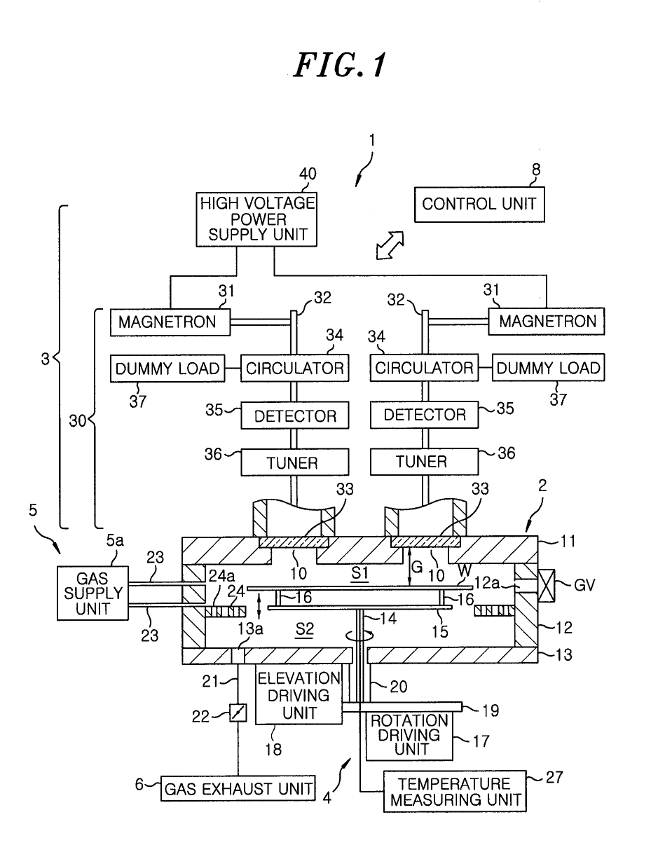

First, a schematic configuration of a microwave heating apparatus in accordance with a first embodiment of the present invention will be described with reference to FIG. 1. FIG. 1 is a cross sectional view showing a schematic configuration of a microwave heating apparatus of the present embodiment. The microwave heating apparatus 1 of the present embodiment performs, through a series of consecutive operations, an annealing process by irradiating microwaves to, e.g., a semiconductor wafer (hereinafter, simply referred to as “wafer”) W used for manufacturing semiconductor devices.

The microwave heating apparatus 1 includes: a processing chamber 2 for accommodating a wafer W that is an object to be processed; a microwave introducing unit 3 for introducing microwaves into the processing chamber 2; a supporting unit 4 for supporting the wafer W in the processing chamber 2; a gas supply mechanism 5 for supplying a gas into the processing chamber 2; a gas exhaust unit 6 for vacuum-exhausting the processing chamber 2; and a control unit 8 for controlling the respective components of the microwave heating apparatus 1.

<Processing Chamber>

The processing chamber 2 is made of a metal, e.g., aluminum, aluminum alloy, stainless steel or the like.

The processing chamber 2 includes: a plate-shaped ceiling portion 11 serving as a top wall; a bottom portion 13 serving as a bottom wall; a square tube-shaped sidewall that connects the ceiling portion 11 and the bottom portion 13; a plurality of microwave introduction ports 10 vertically penetrating through the ceiling portion 11; a loading/unloading port 12a provided at the sidewall 12; and a gas exhaust port 13a provided at the bottom portion 13. The sidewall 12 may be formed in a cylindrical shape. The loading/unloading port 12a allows the wafer W to be transferred between the processing chamber 2 and a transfer chamber (not shown) adjacent thereto. A gate valve GV is provided between the processing chamber 2 and the transfer chamber. The gate valve GV has a function of opening and closing the loading/unloading port 12a. When the gate valve GV is closed, the processing chamber 2 is airtightly sealed. When the gate valve GV is opened, the wafer W can be transferred between the processing chamber 2 and the transfer chamber.

<Microwave Introducing Unit>

The microwave introducing unit 3 is provided above the processing chamber 2 and serves as a unit for introducing electromagnetic waves (microwaves) into the processing chamber 2. The configuration of the microwave introducing unit 3 will be later described in detail.

<Supporting Unit>

The supporting unit 4 includes: a tubular shaft 14 that penetrates through substantially the center of the bottom portion 13 of the processing chamber 2 to extend to the outside of the processing chamber 2; a dielectric plate that is a dielectric member provided substantially horizontally at an upper end portion of the shaft 14; and a plurality of supporting pins 16 as supporting members detachably attached to the peripheral portion of the dielectric plate 15. The supporting unit 4 further includes a rotation driving unit 17 for rotating the shaft 14; an elevation driving unit 18 for vertically displacing the shaft 14; and a movable connection unit 19 for supporting the shaft 14 and connecting the rotation driving unit 17 and the elevation driving unit 18. The rotation driving unit 17, the elevation driving unit 18 and the movable connection unit 19 are provided at the outside of the processing chamber 2. If the inside of the processing chamber 2 needs to be in a vacuum state, a sealing device 20, e.g., a bellows or the like, may be provided around the portion where the shaft 14 penetrates through the bottom portion 13.

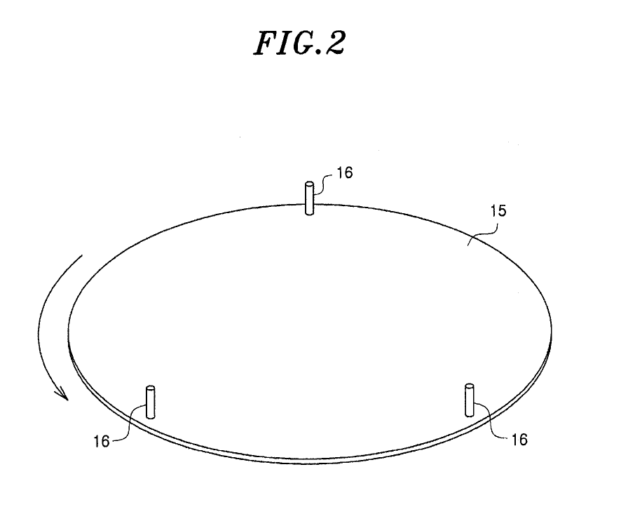

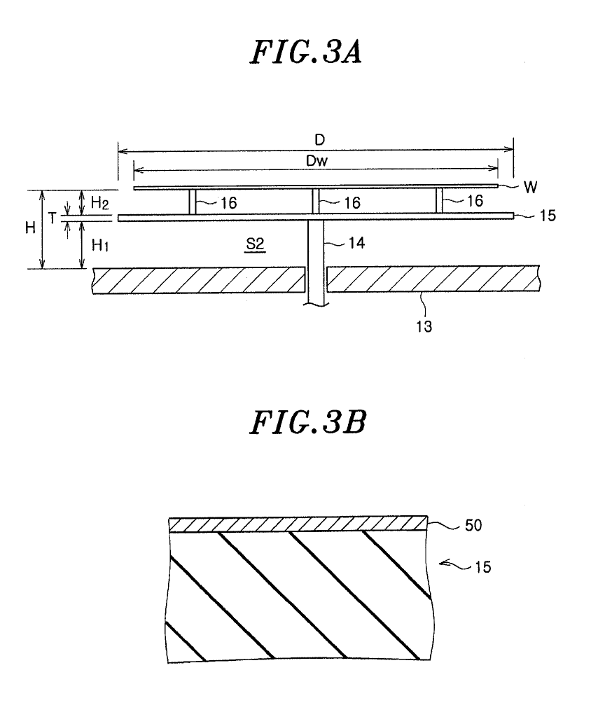

FIG. 2 is a perspective view showing the dielectric plate 15 to which the supporting pins 16 are installed. FIG. 3A is a side view for explaining vertical positions of the dielectric plate 15, the supporting pins 16 and the wafer W supported on the supporting pins 16. A plurality of (three in the present embodiment) supporting pins 16 comes in contact with the backside of the wafer W to support the wafer W in the processing chamber 2. The supporting pins 16 are disposed such that the upper end portions thereof are arranged along the circumferential direction of the wafer W. The supporting pins 16 are detachably attached to the dielectric plate 15. The supporting pins 16 and the dielectric plate 15 are made of a dielectric material. As for the dielectric material, it is possible to use, e.g., quartz, ceramic or the like.

Below the wafer W, the dielectric plate 15 is disposed between the wafer W and the bottom portion 13 of the processing chamber 2 while being separated from the wafer W and the bottom portion 13. In the present embodiment, the dielectric plate 15 is a component of the supporting unit 4 for supporting the wafer W and serves as a microwave absorption promoting unit for promoting absorption of a microwave to the wafer W by changing the state of the microwave below the wafer W. In order to make the dielectric plate 15 effectively function as the microwave absorption promoting unit, a height H₁ from the top surface of the bottom portion 13 to the bottom surface of the dielectric plate 15 may be set within a range from, e.g., about 3 mm to 30 mm and preferably within a range from about 5 mm to 15 mm.

The supporting pins 16 have protrusion heights that allow the wafer W to be separated from the dielectric plate 15 by a predetermined gap. The protrusion heights of the supporting pins 16 are equal to a height H₂ from the top surface of the dielectric plate 15 to the backside of the wafer W which is shown in FIG. 3A. The height H₂ may be set within a range from about 3 mm to 30 mm and preferably within a range from about 5 mm to 15 mm, in order to make the dielectric plate 15 effectively function as a microwave absorption promoting unit. The height H₂ may be adjusted by replacing the supporting pins 16. The number of the supporting pins 16 is not limited to three as long as the wafer W can be stably supported.

In the present embodiment, the wafer W and the dielectric plate 15 have circular plate shapes. A diameter D of the dielectric plate 15 is preferably equal to or greater than a diameter D_{W} of the wafer W. The dielectric plate 15 may have any shape as long as it has a function of changing the state of the microwave below the wafer W. For example, the dielectric plate 15 may have a grid pattern with openings each having a diameter of about 1 mm or less, or the like. A thickness T of the dielectric plate 15 affects the efficiency of absorption of the microwave by the wafer W. In order to make the dielectric plate 15 effectively function as a microwave absorption promoting unit, the thickness T is preferably set within a range from, e.g., about 2 mm to 20 mm, in consideration of the height H₁ from the top surface of the bottom portion 13 to the bottom surface of the dielectric plate 15, and the height H₂ from the top surface of the dielectric plate 15 to the backside of the wafer W.

FIG. 3B is an enlarged cross sectional view showing a structure around the top surface of the dielectric plate 15 in the present embodiment. As shown in FIG. 3B, a metal thin film 50 having a function of reflecting infrared rays may be formed on the top surface of the dielectric plate 15, the top surface facing the wafer W supported by the supporting pins 16. The metal thin film 50 may be, e.g., an aluminum thin film. Since the dielectric material, e.g., quartz, forming the dielectric plate 15 has a large heat capacity, radiant heat from the wafer W heated by the microwave is absorbed by the dielectric plate 15 and this deteriorates the efficiency of heating the wafer W. To that end, the metal thin film 50 that has a feature that reflects the infrared rays is formed on the top surface of the dielectric plate 15. Accordingly, the radiant heat from the wafer W is reflected on the surface of the metal thin film 50 and the efficiency of heating the wafer W can be improved. To do so, the thickness of the metal thin film 50 may be set within a range from, e.g. 10 nm to 500 nm, and preferably within a range from 50 nm to 200 nm. When the thickness of the metal thin film 50 is smaller than 10 nm, the function of reflecting the infrared rays cannot be sufficiently realized. On the other hand, when the thickness of the metal thin film 50 is greater than 500 nm, the microwaves cannot easily penetrate through the dielectric plate 15, which is not preferable.

In the supporting unit 4, the shaft 14, the dielectric plate 15, the rotation driving unit 17 and the movable connection unit 19 constitute a rotation mechanism for rotating, in a horizontal plane, the wafer W supported by the supporting pins 16. By driving the rotation driving unit 17, the supporting pins 16 and the dielectric plate 15 are rotated about the shaft 14 to allow each of the supporting pins 16 to be circularly moved (revolved) horizontally about a center axis of the wafer W supported by the supporting pins 16. Further, in the supporting unit 4, the shaft 14, the dielectric plate 15, the elevation driving unit 18 and the movable connection unit 19 constitute a vertical position control mechanism for controlling a vertical position of the wafer W supported by the supporting pins 16. By driving the elevation driving unit 18, the supporting pins 16 and the dielectric plate 15 are vertically displaced together with the shaft 14.

The rotation driving unit 17 is not particularly limited as long as it can rotate the shaft 14. For example, the rotation driving unit 17 may have a motor (not shown) or the like. The elevation driving unit 18 is not particularly limited as long as it can vertically displace the shaft 14 and the movable connection unit 19. For example, the elevation driving unit 18 may have a ball screw (not shown) or the like. The rotation driving unit 17 and the elevation driving unit 18 may be formed as one unit, and the movable connection unit 19 may be omitted. The rotation mechanism for rotating the wafer W in a horizontal plane and the vertical position control mechanism for controlling the vertical position of the wafer W may have another configuration as long as the functions thereof can be realized.

<Gas Exhaust Unit>

The gas exhaust unit 6 may have a vacuum pump, e.g., a dry pump or the like. The microwave heating apparatus 1 further includes a gas exhaust line 21 for connecting the gas exhaust port 13a and the gas exhaust unit 6, and a pressure control valve 22 disposed on the gas exhaust line 21. By operating the vacuum pump of the gas exhaust unit 6, the inner space of the processing chamber 2 is vacuum-exhausted. The microwave heating apparatus 1 may perform processing under the atmospheric pressure. In this case, the vacuum pump may be omitted. As for the gas exhaust unit 6, a gas exhaust equipment provided at a facility where the microwave heating apparatus 1 is installed may be used instead of the vacuum pump such as a dry pump or the like.

<Gas Supply Mechanism>

The microwave heating apparatus 1 further includes a gas supply mechanism 5 for supplying a gas into the processing chamber 2. The gas supply mechanism 5 includes: a gas supply unit 5a having a gas supply source (not shown); and a plurality of gas supply lines 23, connected to the gas supply unit 5a, for introducing a processing gas into the processing chamber 2. The gas supply lines 23 are connected to the sidewall 12 of the processing chamber 2.

The gas supply unit 5a is configured to supply a processing gas or a cooling gas, e.g., N₂, Ar, He, Ne, O₂, H₂ or the like, into the processing chamber 2 through the gas supply lines 23 in a side flow manner. Alternatively, a gas supply unit may be provided at a position opposite to the wafer W (e.g., the ceiling portion 11) to supply the gas into the processing chamber 2. Instead of the gas supply unit 5a, an external gas supply unit that is not included in the configuration of the microwave heating apparatus 1 may be used. Although it is not illustrated, the microwave heating apparatus 1 further includes mass flow controllers and opening/closing valves which are provided on the gas supply lines 23. The types or the flow rates of the gases supplied into the processing chamber 2 are controlled by the mass flow controllers and the opening/closing valves.

<Rectifying Plate>

The microwave heating apparatus 1 further includes a frame-shaped rectifying plate 24 between the sidewall 12 and the periphery of the supporting pins 16 in the processing chamber 2. The rectifying plate 24 has a plurality of rectifying openings 24a provided to vertically penetrate through the rectifying plate 24. The rectifying plate 24 allows the gas to flow toward the gas exhaust port 13a while rectifying an atmosphere in an area where the wafer W is disposed in the processing chamber 2. The rectifying plate is made of a metal, e.g., aluminum, aluminum alloy, stainless steel or the like. The rectifying plate 24 is not an essential component for the microwave heating apparatus 1 and thus may not be provided.

<Temperature Measurement Unit>

The microwave heating apparatus 1 further includes a plurality of radiation thermometers for measuring a surface temperature of the wafer W, and a temperature measurement unit 27 connected to the radiation thermometers.

<Microwave Radiation Space>

In the microwave heating apparatus 1 of the present embodiment, a space defined by the ceiling portion 11, the sidewall 12 and the rectifying plate 24 in the processing chamber 2 forms a microwave radiation space S1. Microwaves are radiated into the microwave radiation space S1 through the microwave introduction ports 10 provided at the ceiling portion 11. Since each of the ceiling portion 11, the sidewall 12 and the rectifying plate 24 of the processing chamber 2 is made of a metal, the microwaves are reflected by them to be scattered in the microwave radiation space S1.

<Microwave Introducing Unit>

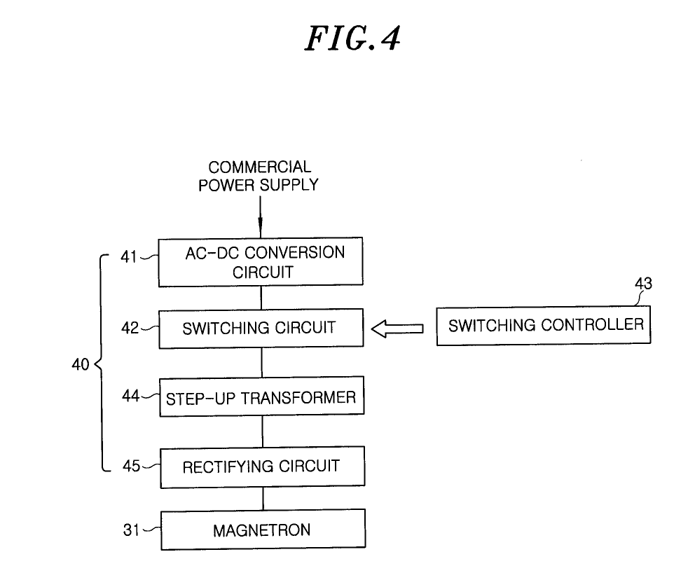

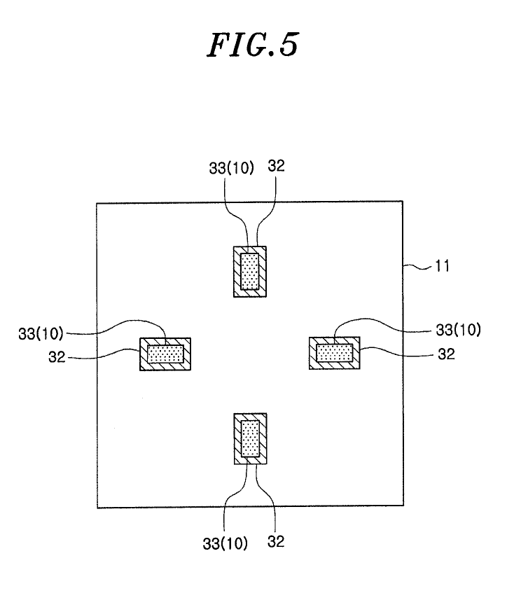

Hereinafter, the configuration of the microwave introducing unit 3 will be described with reference to FIGS. 1, 4 and 5. FIG. 4 is a view for explaining a schematic configuration of a high voltage power supply unit of the microwave introducing unit 3. FIG. 5 is a top view showing a surface of the ceiling portion 11 of the processing chamber 2 shown in FIG. 1.

As described above, the microwave introducing unit 3 is provided above the processing chamber 2 and introduces electromagnetic waves (microwaves) into the processing chamber 2. As shown in FIG. 1, the microwave introducing unit 3 includes a plurality of microwave units 30 for introducing microwaves into the processing chamber 2, and a high voltage power supply unit 40 connected to the microwave units 30.

(Microwave Unit)

In the present embodiment, each of the microwave units 30 has the same configuration. Each of the microwave units 30 includes: a magnetron 31 for generating microwaves for processing the wafer W; a waveguide 32 through which the microwaves generated by the magnetron 31 are transmitted to the processing chamber 2; and a transmitting window 33 that is fixed to the ceiling portion 11 to cover the microwave introduction ports 10. The magnetron 31 serves as a microwave source in the present embodiment.

As shown in FIG. 5, in the present embodiment, the processing chamber 2 has four microwave introduction ports that are spaced apart from each other at a regular interval along the circumferential direction so as to form a substantially cross shape at the ceiling portion 11. Each of the microwave introduction ports 10 is formed in a rectangular shape having shorts sides and long sides when seen from the top. Although the microwave introduction ports 10 may have different sizes or different ratios between the long sides and the short sides, it is preferable that all the four microwave introduction ports 10 have the same size and the same shape in order to increase the uniformity and controllability of the heating process for the wafer W. In the present embodiment, the microwave units 30 are respectively connected to the microwave introduction ports 10. In other words, the number of the microwave units 30 is four.

The magnetron 31 has an anode and a cathode (both not shown) to which a high voltage supplied by the high voltage power supply unit 40 is applied. As for the magnetron 31, one capable of oscillating microwaves of various frequencies may be used. The frequencies of the microwaves generated by the magnetron 31 are optimally selected depending on types of processing for an object. For example, in case of an annealing process, the microwaves having a high frequency of 2.45 GHz, 5.8 GHz or the like are preferably used and the microwaves having a frequency of 5.8 GHz are more preferably used.

The waveguide 32 has a tube shape with a rectangular cross section and extends upward from the top surface of the ceiling portion 11 of the processing chamber 2. The magnetron 31 is connected to an upper end portion of the waveguide 32. The lower end of the waveguide 32 is in contact with the top surface of the transmitting window 33. The microwaves generated by the magnetron 31 are introduced into the processing chamber 2 through the waveguide 32 and the transmitting window 33.

The transmitting window 33 is made of a dielectric material, e.g., quartz, ceramic or the like. The space between the transmitting window 33 and the ceiling portion 11 is airtightly sealed by a sealing member (not shown). A distance (gap G) from the bottom surface of the transmitting window 33 to the surface of the wafer W supported by the supporting pins 16 is preferably set to, e.g., 25 mm or more and more preferably set within a range from 25 mm to 50 mm, in view of suppressing direct irradiation of the microwaves to the wafer W.

The microwave introducing unit 30 further includes a circulator 34, a detector 35, and a tuner 36 which are provided on the waveguide 32; and a dummy load 37 connected to the circulator 34. The circulator 34, the detector 35 and the tuner 36 are provided in that order from the upper end side of the waveguide 32. The circulator 34 and the dummy load 37 serve as an isolator for separating reflection waves from the processing chamber 2. In other words, the circulator 34 guides the reflection waves from the processing chamber 2 to the dummy load 37, and the dummy load 37 converts the reflection waves guided by the circulator 34 into heat.

The detector 35 detects the reflection waves from the processing chamber 2 in the waveguide 32. The detector 35 includes, e.g., an impedance monitor, specifically a standing wave monitor for detecting an electric field of the standing waves in the waveguide 32. The standing waves monitor may include, e.g., three pins protruding into the inner space of the waveguide 32. The reflection waves from the processing chamber 2 are detected by detecting a location, a phase and an intensity of the electric field of the standing waves by using the standing wave monitor. The detector 35 may include a directional coupler capable of detecting traveling waves and reflection waves.

The tuner 36 has a function of matching an impedance between the magnetron 31 and the processing chamber 2. The tuner 36 performs the impedance matching based on the detection result of the reflection waves by the detector 35. The tuner 36 may include, e.g., a conductor plate (not shown) provided to protrude into and retract from the inner space of the waveguide 32. In that case, by controlling the protruding amount of the conductor plate into the inner space of the waveguide 32, the power amount of the reflection waves can be adjusted and, further, the impedance between the magnetron 31 and the processing chamber 2 can be adjusted.

(High Voltage Power Supply Unit)

The high voltage power supply unit 40 supplies a high voltage for generating microwaves to the magnetron 31. As shown in FIG. 4, the high voltage power supply unit 40 includes an AC-DC conversion circuit 41 connected to a commercial power source; a switching circuit 42 connected to the AC-DC conversion circuit 41; a switching controller 43 for controlling an operation of the switching circuit 42; a step-up transformer 44 connected to the switching circuit 42; and a rectifying circuit 45 connected to the step-up transformer 44. The magnetron 31 is connected to the step-up transformer 44 via the rectifying circuit 45.

The AC-DC conversion circuit 41 is a circuit which rectifies AC (e.g., three-phase 200V AC) from the commercial power source and converts it into DC of a predetermined waveform. The switching circuit 42 controls on/off of the DC converted by the AC-DC conversion circuit 41. In the switching circuit 42, the switching controller 43 performs phase-shift PWM (Pulse Width Modulation) control or PAM (Pulse Amplitude Modulation) control to generate a pulse-shaped voltage waveform. The step-up transformer 44 boosts the voltage waveform outputted from the switching circuit 42 to a predetermined level. The rectifying circuit 45 rectifies the voltage boosted by the step-up transformer 44 and supplies the rectified voltage to the magnetron 31.

<Control Unit>

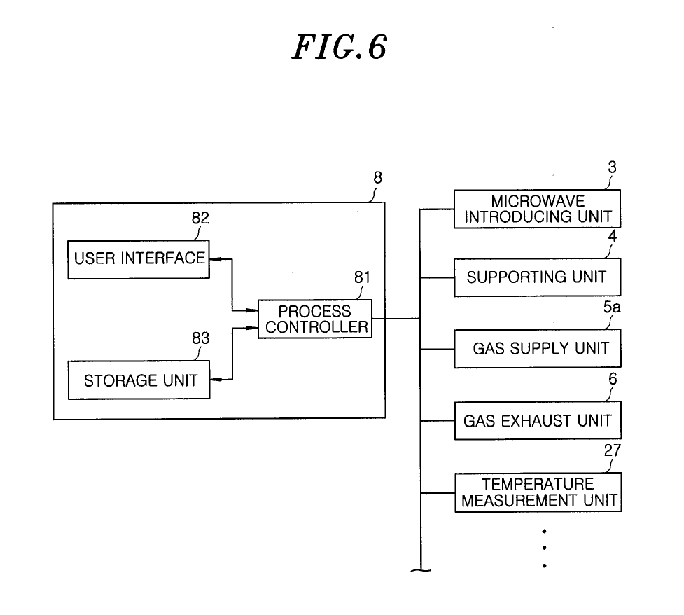

Each of the components of the microwave heating apparatus 1 is connected to the control unit 8 and controlled by the control unit 8. The control unit 8 is typically a computer. FIG. 6 is a view for explaining a configuration of the control unit 8 shown in FIG. 1. In the example shown in FIG. 6, the control unit 8 includes a process controller 81 having a CPU; and a user interface 82 and a storage unit 83 which are connected to the process controller 81.

The process controller 81 performs integrated control of the components (e.g., the microwave introducing unit 3, the supporting unit 4, the gas supply unit 5a, the gas exhaust unit 6, the temperature measurement unit 27 and the like) of the microwave heating apparatus 1 that are related to the process conditions such as a temperature, a pressure, a gas flow rate, power of a microwave, a rotation speed of the wafer W and the like.

The user interface 82 includes a keyboard or a touch panel through which a process manager inputs commands to operate the microwave heating apparatus 1; a display for visually displaying the operation status of the microwave heating apparatus 1; and the like.

The storage unit 83 stores therein control programs (software) for realizing various processes to be performed by the microwave heating apparatus 1 under the control of the process controller 81; and recipes including process condition data and the like. The process controller 81 retrieves and executes a control program and a recipe from the storage unit 83 when necessary, e.g., based on an instruction from the user interface 82. Accordingly, a desired process is performed in the processing chamber 2 of the microwave heating apparatus 1 under the control of the process controller 81.

The control programs and the recipes may be stored in a computer-readable storage medium, e.g., a CD-ROM, a hard disk, a flexible disk, a flash memory, a DVD, a Blu-ray disc or the like. The recipes may be transmitted on-line from another device through, e.g., a dedicated line, when necessary.

<Effects>

Hereinafter, the functional effects of the microwave heating apparatus 1 of the present embodiment will be described. As described above, the dielectric plate 15 is disposed between the wafer W and the bottom portion 13 of the processing chamber 2 while being separated from the wafer W and increases the absorption of microwaves by the wafer W by changing the state of the microwaves below the wafer W. Although it is not clear why the efficiency of absorption of microwaves by the wafer W is increased by interposing the dielectric plate 15 between the wafer W and the bottom portion 13 of the processing chamber 2, it may be reasonably explained as follows. The microwaves introduced into the processing chamber 2 through the microwave inlet ports 10 generate standing waves in a space S2 between the wafer W and the bottom portion 13 of the processing chamber 2. By providing in the space S2 the dielectric plate 15 made of a dielectric material that transmits microwaves, the standing waves in the space S2 can be close to a resonance state. Due to the resonance state, the microwaves are confined in the space S2. When the microwaves are confined, the microwaves incident into the space S2 and the reflection waves from the space S2 are canceled by each other. Accordingly, the efficiency of absorption of the microwaves by the wafer W is improved and the heating of the wafer W is promoted. Hence, in the microwave heating apparatus 1 of the present embodiment, in order to improve the efficiency of absorption of microwaves by the wafer W, the dielectric plate 15 is provided such that the height H (H=H₁+T+H₂) from the bottom portion 13 of the processing chamber 2 to the backside of the wafer W and a wavelength λ₀ of the standing waves (approximately equal to a guide wavelength λ_{g}) generated in the space S2 satisfies a condition of H=n×λ₀/2 (where, n is a positive integer). Specifically, it is preferable to set the height H₁, the thickness T and the height H₂ such that the condition of H=n×λ₀/2 is satisfied.

In the present embodiment, the annealing process is performed while the wafer W supported by the supporting pins is horizontally rotated at a predetermined speed by driving the rotation driving unit 17. As a consequence, over the surface of the wafer W, the radiation of the microwaves in the circumferential direction becomes uniform. Accordingly, the rotation enables the annealing process to be uniformly performed in the circumferential direction over the surface of the wafer W.

<Processing Sequence>

Hereinafter, a processing sequence for performing an annealing process on a wafer W in the microwave heating apparatus 1 will be described. First, a command for performing the annealing process in the microwave heating apparatus 1 is inputted from the user interface 82 to the process controller 81. Next, the process controller 81 receives the command and reads out the recipes that have been stored in the storage unit 83 or the computer-readable storage medium. Then, the process controller 81 transmits control signals to the end devices (e.g., the microwave introducing unit 3, the supporting unit 4, the gas supply unit 5a, the gas exhaust unit 6 and the like) of the microwave heating apparatus 1 such that the annealing process is performed under the conditions based on the recipes.

Next, the gate valve GV is opened, and the wafer W is loaded into the processing chamber 2 through the gate valve GV and the loading/unloading port 12a by a transfer unit (not shown). The wafer W is mounted on the supporting pins 16. The elevation driving unit 18 is driven, so that the supporting pins 16 are vertically moved together with the shaft 14 and the dielectric plate 15 to set the wafer W to a predetermined height H. This height H can be set in consideration of the wavelength λ₀ of the standing wave, the height H₁, the thickness T and the height H₂. Then, at this height H, the wafer W is rotated horizontally at a predetermined speed by driving the rotation driving unit 17. The wafer W may not be rotated continuously, i.e., may be rotated discontinuously. Thereafter, the gate valve GV is closed, and the processing chamber 2 is vacuum-evacuated by the gas exhaust unit 6, if necessary. Next, a processing gas is introduced at a predetermined flow rate into the processing chamber 2 by the gas supply unit 5a. The inner space of the processing chamber 2 is controlled to a predetermined pressure by adjusting a gas exhaust amount and a gas supply amount.

Thereafter, microwaves are generated by applying a voltage from the high voltage power supply unit 40 to the magnetron 31. The microwaves generated by the magnetron 31 are transmitted through the waveguide 32 and the transmitting window 33, and introduced into a space above the wafer W in the processing chamber 2. In the present embodiment, microwaves are sequentially generated by the magnetrons 31 and introduced alternately into the processing chamber 2 through each of the microwave introduction ports 10. Alternatively, the microwaves may be simultaneously generated by the magnetrons 31 and simultaneously introduced into the processing chamber 2 through the microwave introduction ports 10.

The microwaves introduced into the processing chamber 2 are radiated to the rotating wafer W, and the wafer W is rapidly heated by electromagnetic wave heat such as Joule heat, magnetic heat, inductive heat or the like. As a result, the annealing process is performed on the wafer W. Here, the heating efficiency of the wafer W can be increased by setting the height H of the wafer W in consideration of the wavelength λ₀ of the standing wave, the height H₁, the thickness T and the height H₂. The height H of the wafer W can be varied during the annealing process. When the wafer W is rotated by the supporting unit 4 during the annealing process, the heating temperature over the surface of the wafer W can be more uniform by reducing the deviation of the microwaves in the circumferential direction of the wafer W.

When a control signal for terminating the annealing process is transmitted from the process controller 81 to the end devices of the microwave heating apparatus 1, the generation of the microwaves and the rotation of the wafer W are stopped and the supply of the processing gas and the cooling gas is stopped. In this manner, the annealing process for the wafer W is terminated. Next, the gate valve GV is opened, the vertical position of the wafer W on the supporting pins 16 is adjusted and then the wafer W is unloaded by the transfer unit (not shown).

The microwave heating apparatus 1 is preferably used for, e.g., an annealing process for activating doping atoms implanted into the diffusion layer in the manufacturing process of semiconductor devices.

As described above, in the microwave hating apparatus and the processing method of the present embodiment, the dielectric plate 15 made of a dielectric material is provided in the space S2 so as to be separated from the wafer W by a predetermined gap in order to increase the absorption of the microwaves over the surface of the wafer W and improve the heating efficiency. In the case of performing the annealing process on the wafer W while rotating the wafer W horizontally at a predetermined speed, the absorption of the microwaves becomes more uniform over the surface of the wafer W. Hence, the microwave heating apparatus and the processing method of the present embodiment enables the heating process to be effectively and uniformly performed on the wafer W.

### Second Embodiment

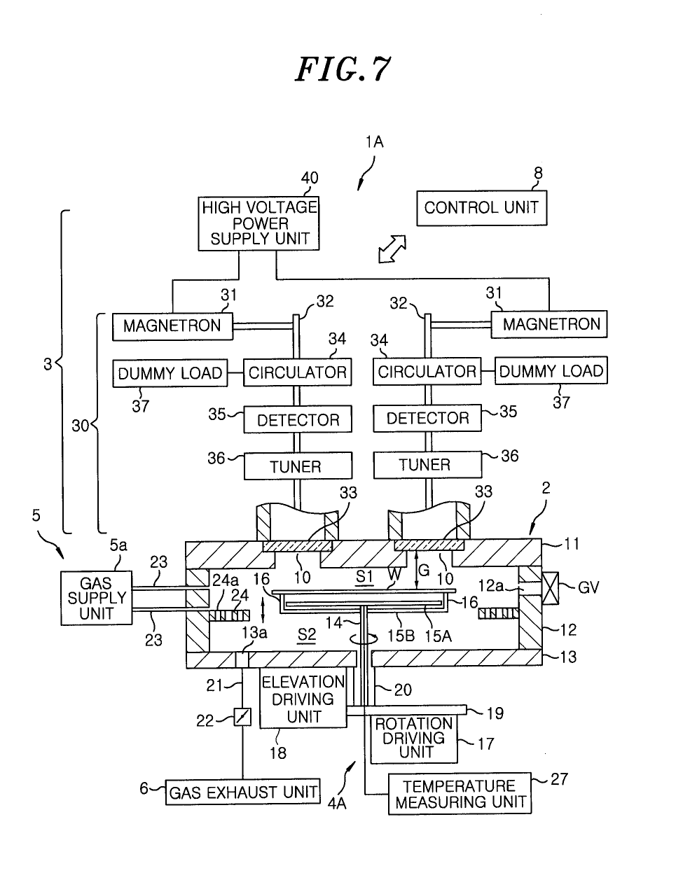

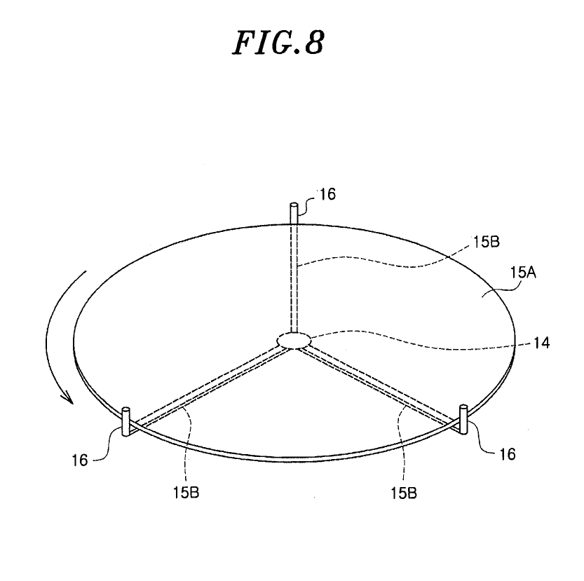

A microwave heating apparatus in accordance with a second embodiment of the present invention will be described with reference to FIGS. 7 and 8. FIG. 7 is a cross sectional view showing a schematic configuration of a microwave heating apparatus 1A of the present embodiment. FIG. 8 is a perspective view showing relationship between the supporting pins 16 and the dielectric plate 15A. The microwave heating apparatus 1A of the present embodiment performs an annealing process by irradiating microwaves to, e.g., a wafer W, through a plurality of consecutive operations. In the following description, differences between the microwave heating apparatus 1 of the first embodiment and the microwave heating apparatus 1A of the present embodiment will be mainly described. In FIGS. 7 and 8, like reference numerals will be used for like parts as those of the microwave heating apparatus 1 of the first embodiment, and redundant description will be omitted.

The microwave heating apparatus 1A of the present embodiment includes: a processing chamber 2 for accommodating therein a wafer W; a microwave introducing unit 3 for introducing microwaves into the processing chamber 2; a supporting unit 4A for supporting the wafer W in the processing chamber 2; a gas supply mechanism 5 for supplying a gas into the processing chamber 2; a gas exhaust unit 6 for vacuum-exhausting the processing chamber 2; and a control unit 8 for controlling the respective components of the microwave heating apparatus 1A.

The supporting unit 4A includes: a tubular shaft 14 that penetrates through substantially the center of the bottom portion 13 of the processing chamber 2 to extend to the outside of the processing chamber 2; a dielectric plate 15A that is a dielectric member provided substantially horizontally at the vicinity of the upper end of the shaft 14; a plurality of arms 15B attached to the shaft 14; a plurality of supporting pins 16 detachably attached to the respective arms 15B. The supporting unit 4A further includes: a rotation driving unit 17 for rotating the shaft 14; an elevation driving unit 18 for vertically displacing the shaft 14; and a movable connection unit 19 for supporting the shaft 14 and connecting the rotation driving unit 17 and the elevation driving unit 18. The number of the arms 15B is equal to the number (e.g., three) of the supporting pins 16. Each arm 15B extends horizontally in a radial direction about the shaft 14. The supporting pins 16 are attached to the vicinity of the leading end of each arm 15B. In the present embodiment, the wafer W and the dielectric plate 15A have circular plate shapes and a diameter of the dielectric plate 15A is smaller than a diameter of the wafer W. Accordingly, the supporting pins 16 are raised upward from the position below the dielectric plate 15A and support the wafer W at the outside of the dielectric plate 15A.

Below the wafer W, the dielectric plate 15A is provided between the wafer W and the bottom portion 13 of the processing chamber 2 while being separated from the wafer W and the bottom portion 13. The dielectric plate 15A serves as a microwave absorption promoting unit for promoting absorption of microwaves to the wafer W by changing the state of microwaves below the wafer W. The dielectric plate 15A has the same function as that of the first embodiment except in that the supporting pins 16 for supporting the wafer W are not installed. In this manner, in the present embodiment, the dielectric plate 15A serving as the microwave absorption promoting unit and the arms 15B for supporting the supporting pins 16 are configured as separate members. The thickness T of the dielectric plate 15A, the height H₁ from the top surface of the bottom portion 13 to the bottom surface of the dielectric plate 15A, the height H₂ from the top surface of the dielectric plate 15A to the backside of the wafer W, and the height H from the top surface of the bottom portion 13 to the backside of the wafer W in the present embodiment may be set as in the first embodiment.

The other configurations and effects of the microwave heating apparatus 1A of the present embodiment are the same as those of the microwave heating apparatus 1 of the first embodiment, so that the description thereof will be omitted. In FIG. 7, the dielectric plate 15A is configured to be rotated and vertically moved together with the arms 15B and the supporting pins 16 by fixing the dielectric plate 15A to the shaft 14. However, the dielectric plate 15A, the arms 15B and the supporting pins 16 may be configured to be rotated and vertically moved by different driving units. In that case, the dielectric plate 15A may be provided not as a component of the supporting unit 4A but as a separate member. In the present embodiment, the dielectric plate 15A may not be rotated or vertically moved. In the present embodiment as well as the first embodiment, the metal thin film 50 may be formed at the dielectric plate 15A.

(Simulation Test)

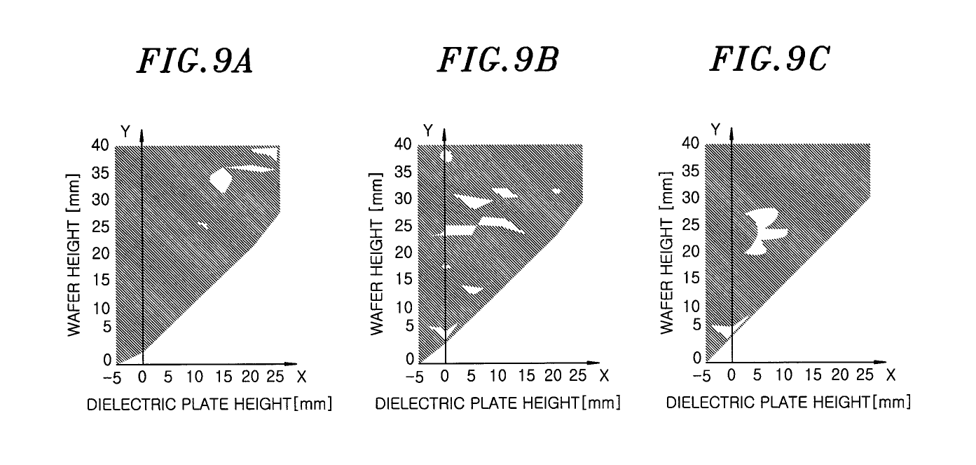

Next, a result of a simulation test that has examined the effects of the present invention will be described with reference to FIGS. 9A to 9C. The efficiency of absorption of microwave power by the wafer W was simulated while varying the thickness T of the dielectric plate 15, the height H₁ from the top surface of the bottom portion 13 to the bottom surface of the dielectric plate 15 (hereinafter, may be referred to as “dielectric plate height H₁”) and the height H from the top surface of the bottom portion 13 to the backside of the wafer W (T+H₁+H₂ in FIG. 3; hereinafter may be referred to as “wafer height H”) in the microwave heating apparatus 1 of the first embodiment (see FIGS. 1 to 6). The thickness T of the dielectric plate 15 was set to 2 mm, 4 mm or 6 mm. The dielectric plate height H₁ was varied within a range from −5 mm to 25 mm. The case in which the thickness T of the dielectric plate 15 is −5 mm indicates that the dielectric plate 15 is not provided. The wafer height H was varied within a range from 0 mm to 40 mm. The other simulation conditions are as follows: the dielectric plate 15 was made of quartz; and the annealing process was performed while rotating the wafer W in a horizontal plane by the supporting unit 4.

FIGS. 9A to 9C show the result of the simulation test. FIG. 9A shows the result obtained when the thickness T of the dielectric plate 15 was 2 mm; FIG. 9B shows the result obtained when the thickness T was 4 mm; and FIG. 9C shows the result obtained when the thickness T was 6 mm. Although the black and white illustration in FIGS. 9A to 9C cannot clearly show the efficiency of the power absorption by the wafer W, it is improved as the color becomes lighter (brighter). The efficiency of the power absorption by the wafer W at the darkest portion is about 70% and that at the brightest portion is about 80%.

It is clear from FIGS. 9A to 9C that the efficiency of the power absorption by the wafer W can be increased by up to about 10% by providing the dielectric plate 15 below the wafer W, compared to the case where the dielectric plate 15 is not provided. Further, it is clear that the efficiency of the power absorption by the wafer W can be changed by varying the thickness T of the dielectric plate 15, the dielectric plate height H₁, and the wafer height H within the above set range. For example, in the above simulation conditions, the ranges of the height H₁ of the dielectric plate and the height H of the wafer where the efficiency of the power absorption by the wafer W can be improved was wide when the thickness T of the dielectric plate 15 was set to 4 mm. Therefore, it is clear that the effect of improving the absorption efficiency of the microwave by the wafer W can be easily obtained in the case of setting the thickness T of the dielectric plate 15 to 4 mm, compared to the case of setting the thickness T to 2 mm or 6 mm. In this manner, the simulation test shows that the annealing process can be effectively performed on the wafer W by providing the dielectric plate 15 and adjusting the thickness T of the dielectric plate 15, the dielectric plate height H₁ and the wafer height H.

The present invention may be variously modified without being limited to the above embodiments. For example, the microwave heating apparatus of the present invention is not limited to the case of using a semiconductor wafer as an object to be processed and may also be applied to a microwave heating apparatus using as a substrate, e.g., a substrate for a solar cell panel or a substrate for a flat panel display.

The number of the microwave units 30 (the number of the magnetrons 31) or the number of the microwave inlet ports 10 in the microwave heating apparatus is not limited to that in the above embodiments.

While the invention has been shown and described with respect to the embodiments, it will be understood by those skilled in the art that various changes and modifications may be made without departing from the scope of the invention as defined in the following claims.

What is claimed is:

1. A microwave heating apparatus comprising:
a processing chamber having a top wall, a bottom wall and a sidewall, and configured to accommodate an object to be processed;
a microwave introducing unit configured to generate a microwave for heating the object and introduce the microwave into the processing chamber;
a plurality of supporting members configured to make contact with the object and support the object in the processing chamber; and
a dielectric member provided between the object supported by the supporting members and the bottom wall while being apart from the object.

2. The microwave heating apparatus of claim 1, wherein the dielectric member is apart from the bottom wall.

3. The microwave heating apparatus of claim 1, wherein the supporting members are attached to the dielectric member.

4. The microwave heating apparatus of claim 3, wherein the object and the dielectric member have circular plate shapes and a diameter of the dielectric member is equal to or greater than a diameter of the object.

5. The microwave heating apparatus of claim 1, further comprising a rotation mechanism configured to circularly move the supporting members in a horizontal plane about a center axis of the object supported by the supporting members.

6. The microwave heating apparatus of claim 1, further comprising a vertical position control mechanism configured to adjust a vertical position of the object supported by the supporting members.

7. The microwave heating apparatus of claim 1, wherein the dielectric member is provided such that a height H from the bottom wall to the object and a wavelength λ₀ of a standing wave generated in a space between the bottom wall and the object satisfies a condition of H=n×λ₀/2, where n is a positive integer.

8. The microwave heating apparatus of claim 1, wherein a metal thin film having a thickness of 10 nm to 500 nm is formed on a top surface of the dielectric member, the top surface facing the object supported by the supporting members.

9. The microwave heating apparatus of claim 1, further comprising a plurality of microwave inlet ports configured to introduce the microwave generated by the microwave introducing unit into the processing chamber, the microwave inlet ports being provided in the top wall of the processing chamber.

10. A processing method comprising:
heating an object to be processed by using a microwave heating apparatus including: a processing chamber having a top wall, a bottom wall and a sidewall, and configured to accommodate the object; a microwave introducing unit configured to generate a microwave for heating the object and introduce the microwave into the processing chamber; a plurality of supporting members configured to make contact with the object to be processed and support the object in the processing chamber; and a dielectric member provided between the object supported by the supporting members and the bottom wall while being apart from the object.

11. The processing method of claim 10, said heating is performed while rotating the object.
